(19) United States
(12) Patent Application Publication
(10) Pub. No.: US 2019/0212396 A1
(43) Pub. Date: Jul. 11, 2019

(54) METHOD AND DEVICE FOR MONITORING HEALTH STATE OF BATTERY OF ELECTRONIC DEVICE, AND DEVICE

(71) Applicant: BEIJING KINGSOFT INTERNET SECURITY SOFTWARE CO., LTD., Beijing (CN)

(72) Inventor: Chengzhi Jiang, Beijing (CN)

(73) Assignee: BEIJING KINGSOFT INTERNET SECURITY SOFTWARE CO., LTD., Beijing (CN)

(21) Appl. No.: 16/224,198

(22) Filed: Dec. 18, 2018

(30) Foreign Application Priority Data
Jan. 10, 2018 (CN) 201810023517.0

(51) Int. Cl. G01R 31/392; H02J 7/02; G01R 31/36

(52) U.S. Cl. CPC G01R 31/392; G01R 31/3648; H02J 7/027

(57) ABSTRACT

The present disclosure provides a method and a device for monitoring a health state of a battery of an electronic device and a device. The method includes: obtaining an initial electric quantity of the battery when determining that the battery of the electronic device is presently in a preset state; obtaining respective instantaneous current values of the battery periodically during the preset state at a preset frequency; obtaining a final electric quantity of the battery when determining that the preset state ends; determining a present actual capacity of the battery based on the initial electric quantity of the battery, the respective instantaneous current values and the final electric quantity of the battery; and determining a present health state of the battery based on the present actual capacity and a design capacity of the battery.

### CROSS-REFERENCE TO RELATED APPLICATIONS

This application is based on and claims priority to Chinese Patent Application No. 201810023517.0, filed on Jan. 10, 2018, the entire contents of which are incorporated herein by reference.

### FIELD

The present disclosure relates to the field of electronic technologies, and more particularly, to a method and a device for monitoring a health state of a battery of an electronic device, and a device.

### BACKGROUND

With the diversification of functions of electronic devices, people are increasingly dependent on electronic devices, making battery life and service life of the electronic devices become one of important issues of concern to users.

In the related art, the battery life and service life of the electronic device is usually monitored by obtaining parameters (such as charging voltage, charging current, discharging voltage, discharging current, etc.) when the battery of the electronic device is charging or discharging, calculating the charged electric quantity or the discharged electric quantity, and presenting the calculated electric quantity percentage of the battery to the user, such that the user can know the remaining electric quantity of the battery of the electronic device.

However, in actual practice, the above manner may not help users to know the aging of the battery of the electronic device. For example, the battery capacity of a brand new mobile phone is 1000 mAh, when the battery is fully charged, the battery voltage is about 4.2V, and the user can know that the electric quantity of the battery is full according to the voltage monitoring result. However, as the usage time increases, the charging times and the discharging times increases, the battery of the mobile phone will gradually age, and the battery capacity will also decrease. Assuming that when the battery is fully charged, the capacity is only 50% of the battery capacity when the mobile phone is brand new, i.e., the capacity is only 500 mAh, since the battery voltage is still 4.2V when the battery is fully charged, the voltage monitoring result will still show that the battery is fully charged, and the user does not know that the usage time of the battery is only 50% of that of the brand new battery. This makes the user feel that the battery is not fully charged or a large amount of power is consumed, such that the user cannot know the health degree of the battery of the electronic device, and the user cannot evaluate whether to replace the electronic device or replace the battery of the electronic device.

### SUMMARY

Embodiments of the present disclosure provide a method for monitoring a health state of a battery of an electronic device. The method includes: obtaining an initial electric quantity of the battery when determining that the battery of the electronic device is presently in a preset state; obtaining respective instantaneous current values of the battery periodically during the preset state at a preset frequency; obtaining a final electric quantity of the battery when determining that the preset state ends; determining a present actual capacity of the battery based on the initial electric quantity of the battery, the respective instantaneous current values and the final electric quantity of the battery; and determining a present health state of the battery based on the present actual capacity and a design capacity of the battery.

Embodiments of the present disclosure provide an electronic device. The electronic device includes a memory, a processor and a computer program stored in the memory and executable on the processor. When the computer program is executed by the processor, the processor is caused to implement the method for monitoring a health state of a battery of an electronic device according to embodiments of the present disclosure.

Embodiments of the present disclosure provide a computer readable storage medium. The computer readable storage medium is configured to store a computer programs that, when executed by a processor, causes the processor to perform the method for monitoring a health state of a battery of an electronic device according to embodiments of the present disclosure.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the accompanying drawings, in which:

FIG. 1 is a flow chart of a method for monitoring a health state of a battery of an electronic device according to an embodiment of the present disclosure;

FIG. 2 is a flow chart of a method for monitoring a health state of a battery of an electronic device according to another embodiment of the present disclosure;

FIG. 3 is a block diagram of a device for monitoring a health state of a battery of an electronic device according to an embodiment of the present disclosure;

FIG. 4 is a block diagram of a device for monitoring a health state of a battery of an electronic device according to another embodiment of the present disclosure; and

FIG. 5 is a block diagram of an electronic device according to an embodiment of the present disclosure.

### DETAILED DESCRIPTION

Reference will be made in detail to embodiments of the present disclosure. Embodiments of the present disclosure will be shown in drawings, in which the same or similar elements and the elements having same or similar functions are denoted by like reference numerals throughout the descriptions. The embodiments described herein according to drawings are explanatory and illustrative, intended to explain the present disclosure, and are not construed to limit the present disclosure.

In the related art, when the battery life and service life of an electronic device are monitored, only the remaining electric quantity of the battery of the electronic device can be provided to the user, the user cannot know the aging condition of the battery of the electronic device, and also cannot know the health condition of the battery of the electronic device to evaluate whether to replace the electronic device or replace the battery of the electronic device, in view of this, embodiments of the present disclosure provide a method for monitoring a health state of a battery of an electronic device.

Embodiments of the present disclosure provide a method for monitoring a health state of a battery of an electronic device, when it is determined that the battery of the electronic device is presently in the preset state, the initial electric quantity of the battery is obtained, respective instantaneous current values of the battery are obtained periodically during the preset state at the preset frequency, and when it is determined that the preset state ends, the final electric quantity of the battery is obtained, the present actual capacity of the battery is determined based on the initial electric quantity of the battery, the respective instantaneous current values and the final electric quantity of the battery, and then the present health state of the battery is determined based on the present actual capacity and the design capacity of the battery. Thus, timely and accurate judgment on the health state of the battery can be realized, which can help the user quickly and accurately know the health condition of the battery of the electronic device in use, such that the user can evaluate whether to replace the electronic device or replace the battery of the electronic device based on the health condition of the battery, reliability for battery monitoring can be improved, and user experience can be improved.

The method and the device for monitoring a health state of a battery of an electronic device and a device according to embodiments of the present disclosure will be described below with reference to the accompanying drawings.

The method for monitoring a health state of a battery of an electronic device according to embodiments of the present disclosure will first be described in detail below with reference to the accompanying drawings.

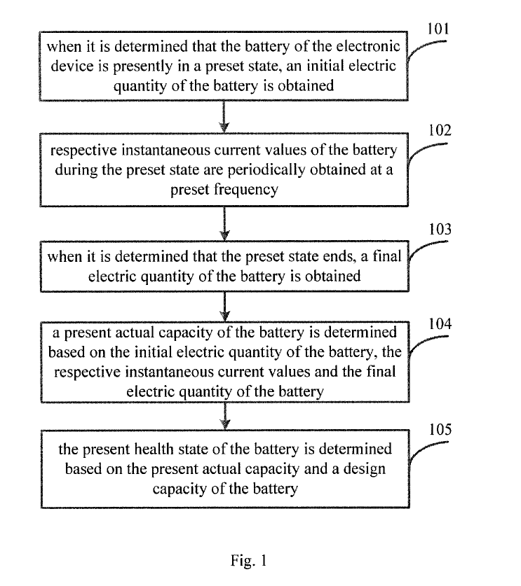

FIG. 1 is a flow chart of a method for monitoring a health state of a battery of an electronic device according to an embodiment of the present disclosure. As illustrated in FIG. 1, the method may include followings.

At block 101, when it is determined that the battery of the electronic device is presently in a preset state, an initial electric quantity of the battery is obtained.

Specifically, the method for monitoring a health state of a battery of an electronic device according to embodiments of the present disclosure may be performed by a device for monitoring a health state of a battery of an electronic device provided by the present disclosure. The device can be configured in an electronic device, to control the electronic device.

In the embodiment, the electronic device may be any hardware device having a battery unit, such as a smart phone, a tablet computer, a personal digital assistant, a notebook computer, a smart speaker, etc., which is not limited in embodiments of the present disclosure.

The preset state of battery may include a discharging state, or an alternating current AC charging state.

It should be noted that, in actual use, the battery charging harness of the electronic device can be used not only to charge the battery, but also to perform data transmission, and both of which can be performed through direct current. Therefore, in order to distinguish whether the electronic device is in normal charging or is in data transmission, in the embodiment, the charging state or the data transmission state of the battery can be determined by determining the name of the triggered line in the harness contact of the electronic device.

Generally, there are at least 4 charging harness contacts in the electronic device, which are positive supply, positive data line, negative data line and ground. When the positive supply and the ground in the charging harness of the electronic device are triggered, it is determined that the electronic device is presently in the charging state. When the positive supply, the positive data line, the negative data line and the ground in the charging harness of the electronic device are all triggered, it is determined that the electronic device is presently in the data transmission state.

In an implementation, a system broadcast message sent by the electronic device may be obtained, and the system broadcast message may be parsed to determine whether a value of a preset field in the system broadcast message is consistent with a preset AC charging state value. When the value of the preset field in the system broadcast message is consistent with the preset AC charging state value, it is determined that the battery is presently in the AC charging state. In the embodiment, the system broadcast message is configured to indicate that an electric quantity of the battery changes.

In the embodiment, the preset AC charging state value may be determined based on a specific field in the battery management system, or determined by other means, which is not specifically limited herein.

The preset field in the system broadcast message can be adaptively set based on actual use requirements, which is not specifically limited in the embodiment.

For example, when the obtained system broadcast message includes:

int_Plugged=Intent.getIntExtra (BatteryManager.EXTRA_PLUGGED, 0);

If(BatteryManager.BATTERY_PLUGGED_AC==_Plugged), it can be determined that the battery of the electronic device is presently in the AC charging state.

Similarly, the determination of the discharging state of the battery may also be implemented by obtaining the system broadcast message sent by the electronic device, etc., and details are not described in the embodiment.

Furthermore, when it is determined that the battery of the electronic device is presently in the preset state, the initial electric quantity of the battery is obtained.

In an implementation, the present electric quantity of the battery may be obtained by calling a battery electric quantity acquisition function (such as int current=intent.getExtras( ).getInt(“level”)).

At block 102, respective instantaneous current values of the battery during the preset state are periodically obtained at a preset frequency.

In the embodiment, the preset frequency may refer to a time interval, such as 5 seconds(s), 10 s, etc., which is not specifically limited herein.

In an implementation, the respective instantaneous current values of the battery during the preset state can be obtained by the following manners.

In an implementation manner, a first system function is called periodically to obtain the respective instantaneous current values of the battery.

The first system function may be any function that can obtain the respective instantaneous current values of the battery, which is not specifically limited in the embodiment.

With the continuous development of electronic technology, in order to meet requirements of different users, the system of the electronic device is constantly updated, this indicates that the more timely the system of the electronic device is updated, the more comprehensive the function of the electronic device is, and the better the performance is.

Therefore, in order to obtain the respective instantaneous current values of the battery during the preset state, the system version of the electronic device may be determined first. When the present system version of the electronic device is the latest version, the respective instantaneous current values of the battery during the preset state can be obtained periodically by calling a battery instantaneous current acquisition function.

For example, when the system version of the electronic device is above Android 5.0, in the embodiment, a battery instantaneous current acquisition function, such as BatteryManager.getIntProperty(BatteryManager. BATTERY_PROPERTY_CURRENT_NOW)), can be called to obtain the respective instantaneous current values of the battery during the preset state.

In another implementation manner, a system file of the electronic device is read periodically to obtain stored respective instantaneous current values of the battery.

Specifically, in actual use, it is inevitable that some users cannot update the system version of the electronic device in time, when the respective instantaneous current values of the battery during the preset state is obtained by the electronic device, the battery instantaneous current acquisition function cannot be used to obtain the respective instantaneous current values of the battery.

In order to solve the above problem, in the embodiment, when it is determined that the system version of the electronic device is below Android 5.0, the respective instantaneous current values stored in the system file can be read.

Furthermore, since the location of the file where the electronic device stores the instantaneous current value of the battery may vary, in the embodiment, in order to obtain the respective instantaneous current values of the battery, the system files of the electronic device may be traversed, such that the respective instantaneous current values corresponding to the battery can be accurately and reliably obtained for different systems.

It should be noted that, in the embodiment, the above-mentioned manners for obtaining the respective instantaneous current values of the battery may be individually implemented, or may be implemented in combination, which is not specifically limited in the embodiment.

At block 103, when it is determined that the preset state ends, a final electric quantity of the battery is obtained.

Specifically, when the system broadcast message sent by the electronic device is obtained and parsed, the final electric quantity of the battery can be obtained when it is determined that the preset state ends.

In a specific implementation, the present final electric quantity of the battery can be obtained by calling the battery electric quantity acquisition function: int current=intent.getExtras( ).getInt(“level”).

At block 104, a present actual capacity of the battery is determined based on the initial electric quantity of the battery, the respective instantaneous current values and the final electric quantity of the battery.

Specifically, in the embodiment, after the initial electric quantity of the battery, the respective instantaneous current values and the final electric quantity of the battery are obtained, the present actual capacity of the battery can be calculated.

In the implementation, the present actual capacity of the battery can be calculated by the following formula (1).

$$C = \frac{{\sum }_{j = 1}^{n} {I}_{j} * t}{3600} * \frac{1}{p} \qquad ( 1 )$$

where, C denotes the present actual capacity of the battery, I denotes the instantaneous current value of the battery during the preset state, t denotes the preset time interval, Iⱼ denotes the instantaneous current of the battery obtained at the j^{th} times during the preset state, n denotes the number of times of obtaining the instantaneous current of the battery during the preset state, and p denotes the percentage of the electric quantity of the battery increased during the preset state.

For example, the initial electric quantity of the battery is 1000 mAh, the instantaneous current of the battery is obtained 5 times during the AC charging state, the time interval is 5 s, the obtained 5 sets of instantaneous current values are 200 mA, 220 mA, 210 mA, 190 mA and 212 mA, respectively, the initial percentage of the electric quantity of the battery is 60%, and the final percentage of the electric quantity of the battery is 62%, and then based on the above formula (1), the present actual capacity of the battery can be calculated as 1072 mAh.

At block 105, the present health state of the battery is determined based on the present actual capacity and a design capacity of the battery.

In the embodiment, the health state of the battery may include health, sub-health, abnormality, etc., which is not specifically limited in this embodiment.

Specifically, in order to accurately evaluate the present health state of the battery, in the embodiment, the design capacity of the battery needs to be obtained first. The design capacity refers to the capacity of the battery set during production of the electronic device.

In detail, the design capacity of the battery may be obtained by various ways, examples are as follows.

Way one, a second system function is called to obtain the design capacity of the battery.

Specifically, in this embodiment, the second system function may be PowerProfile. However, since PowerProfile belongs to the internal class of the Android system, it cannot be directly obtained. In this case, the PowerProfile can be obtained by reflection, and the approach is getAveragePower, and the parameter name in the approach is “battery.capacity”.

Way two, the design capacity of the battery is determined according to setting of a user.

Specifically, since the design capacity of the battery in the electronic device is generally in the range of 800 mAh to 6000 mAh, when the design capacity of the battery obtained by the above way one is not within the range, the electronic device may display a prompt message (such as, failing to obtain the design capacity of the battery, there being an error in obtaining the design capacity of the battery, etc.), in this case, the user may manually set the design capacity of the electronic device based on the above prompt message.

Furthermore, after the design capacity of the battery is obtained, the present health state of the battery can be determined based on the obtained present actual capacity and the design capacity of the battery, and the determined health state of the battery may also be displayed on a client, such that the user can know whether the battery of the electronic device is in good health condition.

Certainly, in the embodiment, in addition to displaying the health state of the battery, messages (such as the present capacity of the battery, the usage time, etc.) may also be displayed.

In an implementation, the present health state of the battery can be determined by the following formula (2).

$$H = \frac{{C}_{1}}{{C}_{0}} * 100 \% \qquad ( 2 )$$

where H denotes the health degree of the battery, C₁ denotes the present actual capacity of the battery, and C₀ denotes the design capacity of the battery.

For example, when the present actual capacity of the battery is 2500 mA, and the design capacity of the battery is 5500 mA, then it can be calculated that the health degree of the battery is 45.5% using the formula (2).When a preset health threshold of the battery is 80%, it indicates that the present health degree of the battery is relatively low, and it may be the aging of the battery due to long time using.

With the method for monitoring a health state of a battery of an electronic device according to embodiments of the present disclosure, when it is determined that the battery of the electronic device is presently in the preset state, the initial electric quantity of the battery is obtained, respective instantaneous current values of the battery are obtained periodically during the preset state at the preset frequency, and when it is determined that the preset state ends, the final electric quantity of the battery is obtained, the present actual capacity of the battery is determined based on the initial electric quantity of the battery, the respective instantaneous current values and the final electric quantity of the battery, and then the present health state of the battery is determined based on the present actual capacity and the design capacity of the battery. Thus, the health condition of the battery can be timely and accurately judged, which can help the user quickly and accurately know the health condition of the battery of the electronic device in use, such that the user can evaluate whether to replace the electronic device or replace the battery of the electronic device based on the health condition of the battery, reliability for battery monitoring can be improved, and user experience can be improved.

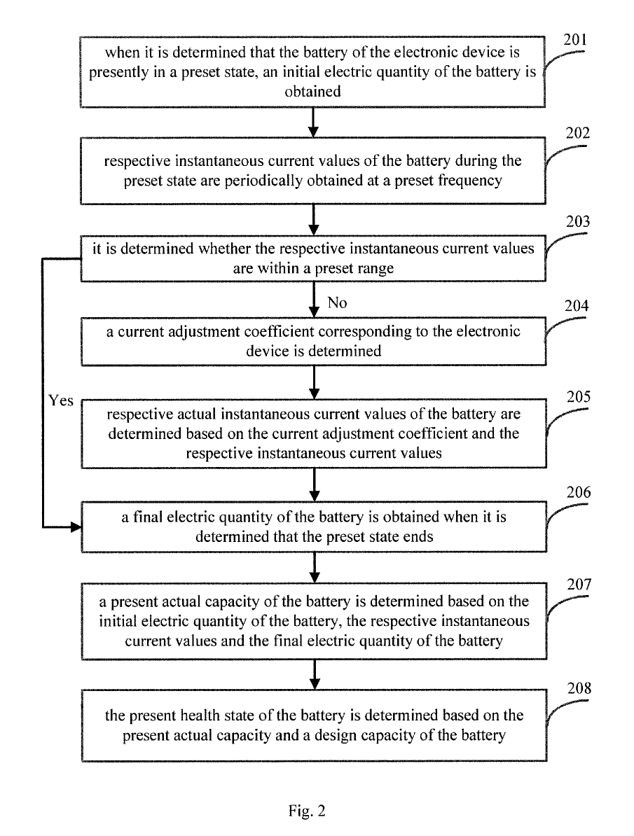

Based on the above analysis, the present health state of the battery is determined by obtaining the present actual capacity and the design capacity of the battery. In an implementation, since the parameters for obtaining the present actual capacity of the battery include the initial electric quantity of the battery, the respective instantaneous current values and the final electric quantity of the battery, in actual applications, the respective instantaneous current values obtained from the system files of the electronic device may usually have been corrected, and there may be errors. Thus, to avoid inaccurate monitoring of the health state of the battery caused by the above error, in the embodiment, the obtained respective instantaneous current values are verified, to ensure the accuracy and reliability of the health state of the battery monitored. In the following, the method for monitoring a health state of a battery of an electronic device according to another embodiment of the present disclosure will be described with reference to FIG. 2.

FIG. 2 is a flow chart of a method for monitoring a health state of a battery of an electronic device according to another embodiment of the present disclosure. As illustrated in FIG. 2, the method for monitoring a health state of a battery of an electronic device may include followings.

At block 201, when it is determined that the battery of the electronic device is presently in a preset state, an initial electric quantity of the battery is obtained.

At block 202, respective instantaneous current values of the battery during the preset state are periodically obtained at a preset frequency.

For specific implementation process and principle of blocks 201-202, reference may be made to the detailed description of the foregoing embodiments, and details are not described herein again.

At block 203, it is determined whether the respective instantaneous current values are within a preset range, if yes, block 206 is performed, and otherwise block 204 is performed.

In the embodiment, the preset range may be adaptively set based on the actual usage condition of the electronic device. For example, the range of charging current may be 250 mA˜400 mA, which is not specifically limited herein.

Specifically, after the respective instantaneous current values of the battery during the preset state are obtained at block 202, the obtained respective instantaneous current values may be matched with the preset range, so as to determine whether the obtained respective instantaneous current values are within the preset range. When the respective instantaneous current values are within the preset range, it indicates that the present respective instantaneous current values obtained are relatively reliable. When the respective instantaneous current values are not within the preset range, it indicates that there may be an error in the respective instantaneous current values obtained. In this case, a current adjustment coefficient corresponding to the electronic device needs to be obtained, to determine respective actual instantaneous current values of the battery.

For example, when the obtained respective instantaneous current values are 150 mA, 180 mA, and 220 mA, and the preset range is 250 mA˜400 mA, it indicates that there is an error in the presently obtained instantaneous current values. In this case, the current adjustment coefficient corresponding to the electronic device needs to be obtained, to determine respective actual instantaneous current values of the battery.

At block 204, a current adjustment coefficient corresponding to the electronic device is determined.

The current adjustment coefficient may be customized by the manufacturer when the electronic device is manufactured, and is not specifically limited in the embodiment.

In the implementation, the current adjustment coefficient corresponding to the electronic device may be determined by following manners, and examples are as follows.

A First Implementation Manner

The current adjustment coefficient corresponding to attribute information of the electronic device is obtained by querying a preset database.

In the embodiment, the preset database may include a database storing mapping tables between various attributes of electronic devices and corresponding current adjustment coefficients, which is not specifically limited in the embodiment.

The attribute information of the electronic device may include, but is not limited to, a device brand, a device model, a device number, and the like. For example, the device brand may include OPPO, Huawei, Lenovo, ZTE, etc.

Generally, the system file of the electronic device may store its attribute information. Therefore, in order to obtain the current adjustment coefficient corresponding to the attribute information of the electronic device from the preset database, in the embodiment, a third system function (an attribute function) may be called first to obtain the attribute information of the electronic device from the system file.

In an implementation, a device brand acquisition function (such as Build.BRAND) may be called to obtain the device brand, or a device model acquisition function (such as Build.MODEL.trim( )) may be called to obtain the device model, or a device number acquisition function (such as Build. DEVICE) may be called to obtain the device number, etc.

A Second Implementation Manner

The respective instantaneous current values are adjusted by using respective preset adjustment coefficients in sequence to determine respective adjusted instantaneous current values, and the adjustment coefficient corresponding to the adjusted instantaneous current values within the preset range is determined as the current adjustment coefficient corresponding to the electronic device.

The preset adjustment coefficient may be default current adjustment coefficients used in the field, such as 1, 10, 100, 1000, −1, −10, −100, −1000, etc.

Specifically, since the preset database is manually set, the attribute information of some electronic devices may not be recorded in the preset database. In this case, when the corresponding current adjustment coefficient is queried in the preset database based on the attribute information of the electronic device, the query may fail, or the current adjustment coefficient corresponding to the attribute information may not be obtained.

Accordingly, in the embodiment, in order to solve the above problem, the respective instantaneous current values may be adjusted based on the current adjustment coefficient generally set in the art, so as to determine the respective adjusted instantaneous current values.

The respective instantaneous current values of the battery obtained during the preset state are usually obtained by multiplying the true instantaneous current value by a certain multiple.

In the embodiment, the respective instantaneous current values are adjusted by each preset adjustment coefficient. In an implementation, the obtained respective current instantaneous values may be divided by each of the preset adjustment coefficients (such as current adjustment coefficients normally set in the art). For example, the obtained respective current instantaneous values may be divided by each of the preset adjustment coefficients 1, 10, 100 and 1000, and four sets of adjusted instantaneous current values can be obtained correspondingly, and then the four sets of adjusted instantaneous current values can be compared with the preset range respectively, when the second set of adjusted instantaneous current values are within the preset range, the current adjustment coefficient corresponding to the electronic device can be determined as 10.

A Third Implementation Manner

An average value of the respective instantaneous current values is adjusted by using respective preset adjustment coefficients in sequence to determine adjusted current average values, and the adjustment coefficient corresponding to the adjusted current average values within the preset range is determined as the current adjustment coefficient corresponding to the electronic device.

Specifically, the adjusted instantaneous current values obtained by the second implementation manner may be partially within the preset range, and may be partially not within the preset range, thus the current adjustment coefficient corresponding to the electronic device may not be accurately determined.

Accordingly, in order to solve the above problem, the obtained respective instantaneous current values may be averaged to obtain an average value of the respective instantaneous current values, and then the average value of the respective instantaneous current values can be adjusted by each of the preset adjustment coefficients, to determine multiple sets of adjusted current average values. Then, the multiple sets of adjusted current average values are compared with the preset range respectively, when a set of adjusted current average values are within the preset range, the adjustment coefficient corresponding to the set of adjusted current average values is determined as the current adjustment coefficient corresponding to the electronic device.

Furthermore, when there are at least two adjustment coefficients corresponding to the adjusted current average values within the preset range, the adjustment coefficient corresponding to the maximum adjusted current average values may be determined as the current adjustment coefficient corresponding to the electronic device.

At block 205, respective actual instantaneous current values of the battery are determined based on the current adjustment coefficient and the respective instantaneous current values.

In detail, after the current adjustment coefficient corresponding to the electronic device is determined, the respective actual instantaneous current values of the battery can be determined based on the current adjustment coefficient and the respective instantaneous current values.

In an implementation, the respective actual instantaneous current values of the battery may be determined by dividing the respective instantaneous current values by the current adjustment coefficient.

At block 206, a final electric quantity of the battery is obtained when it is determined that the preset state ends.

At block 207, a present actual capacity of the battery is determined based on the initial electric quantity of the battery, the respective instantaneous current values and the final electric quantity of the battery.

When the obtained respective instantaneous current values are within the preset range, the present actual capacity of the battery can be determined directly based on the instantaneous current values, the initial electric quantity of the battery and the final electric quantity of the battery. When the obtained respective instantaneous current values are not within the preset range, the respective actual instantaneous current values of the battery can be determined based on the determined current adjustment coefficient and the respective instantaneous current values, and the present actual capacity of the battery can be determined based on the respective actual instantaneous current values, the initial electric quantity of the battery and the final electric quantity of the battery.

At block 208, the present health state of the battery is determined based on the present actual capacity and a design capacity of the battery.

With the method for monitoring a health state of a battery of an electronic device according to embodiments of the present disclosure, when it is determined that the battery of the electronic device is presently in the preset state, the initial electric quantity of the battery is obtained, and respective instantaneous current values of the battery are obtained periodically during the preset state at the preset frequency, after the respective instantaneous current values of the battery during the preset state are obtained, it is determined whether the respective instantaneous current values are within the preset range, when the respective instantaneous current values are not within the preset range, the current adjustment coefficient corresponding to the electronic device is determined, and the respective actual instantaneous current values of the battery are determined based on the determined current adjustment coefficient and the respective instantaneous current values, when the preset state ends, the final electric quantity of the battery is obtained, and the present actual capacity of the battery is determined based on the initial electric quantity of the battery, the respective actual instantaneous current values and the final electric quantity of the battery, and then the present health state of the battery is determined based on the present actual capacity and the design capacity of the battery. Thus, the health condition of the battery can be timely and accurately judged, which can help the user quickly and accurately know the health condition of the battery of the electronic device in use, such that the user can evaluate whether to replace the electronic device or replace the battery of the electronic device based on the health condition of the battery, reliability for battery monitoring can be improved, and user experience can be improved. Moreover, by verifying the obtained instantaneous current values, the accuracy of the finally obtained health state of the battery can be improved.

In order to achieve the above embodiments, the present disclosure further provides a device for monitoring a health state of a battery of an electronic device.

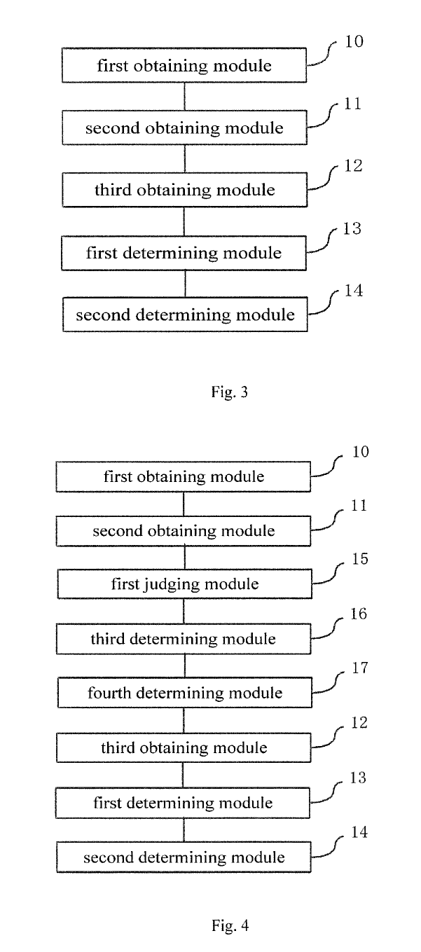

FIG. 3 is a block diagram of a device for monitoring a health state of a battery of an electronic device according to an embodiment of the present disclosure.

As illustrated in FIG. 3, the device for monitoring a health state of a battery of an electronic device may include a first obtaining module 10, a second obtaining module 11, a third obtaining module 12, a first determining module 13, and a second determining module 14.

The first obtaining module 10 is configured to obtain an initial electric quantity of the battery when determining that the battery of the electronic device is presently in a preset state.

The second obtaining module 11 is configured to obtain respective instantaneous current values of the battery periodically during the preset state at a preset frequency.

The third obtaining module 12 is configured to obtain a final electric quantity of the battery when determining that the preset state ends.

The first determining module 13 is configured to determine a present actual capacity of the battery based on the initial electric quantity of the battery, the respective instantaneous current values and the final electric quantity of the battery.

The second obtaining module 14 is configured to determine a present health state of the battery based on the present actual capacity and a design capacity of the battery.

Further, in a possible implementation, when the first obtaining module 10 is configured to determine the preset state of the battery, the first obtaining module 10 is configured to determine that the battery is presently in a discharging state, or determine that the battery is presently in an alternating current AC charging state.

In another possible implementation, the first obtaining module 10 includes a first obtaining sub unit and a first determining sub unit.

The first obtaining sub unit is configured to obtain a system broadcast message sent by the electronic device. The system broadcast message is configured to indicate that an electric quantity of the battery changes. The first determining sub unit is configured to determine that the battery is presently in the AC charging state when a value of a preset field in the system broadcast message is consistent with a preset AC charging state value.

In another possible implementation, the second obtaining module 11 is further configured to call a first system function periodically to obtain the respective instantaneous current values of the battery, or read a system file of the electronic device periodically to obtain stored respective instantaneous current values of the battery.

In another possible implementation, the second determining module 14 is further configured to call a second system function to obtain the design capacity of the battery; or determine the design capacity of the battery according to setting of a user.

In another possible implementation, as illustrated in FIG. 4, the device further comprises a first judging module 15, a third determining module 16 and a fourth determining module 17.

The first judging module 15 is configured to determine whether the respective instantaneous current values are within a preset range.

The third determining module 16 is configured to determine a current adjustment coefficient corresponding to the electronic device when the respective instantaneous current values are not within the preset range.

The fourth determining module 17 is configured to determine respective actual instantaneous current values of the battery based on the current adjustment coefficient and the respective instantaneous current values.

In another possible implementation, the third determining module 16 is further configured to: obtain the current adjustment coefficient corresponding to attribute information of the electronic device by querying a preset database; or adjust the respective instantaneous current values by using respective preset adjustment coefficients in sequence to determine respective adjusted instantaneous current values, and determine the adjustment coefficient corresponding to the adjusted instantaneous current values within the preset range as the current adjustment coefficient corresponding to the electronic device; or adjust an average value of the respective instantaneous current values by using respective preset adjustment coefficients in sequence to determine adjusted current average values, and determine the adjustment coefficient corresponding to the adjusted current average values within the preset range as the current adjustment coefficient corresponding to the electronic device.

In another embodiment of the present disclosure, the third determining module is further configured to determine an adjustment coefficient corresponding to the maximum adjusted current average value as the current adjustment coefficient corresponding to the electronic device when there are at least two adjustment coefficients corresponding to the adjusted current average values within the preset range.

In another embodiment of the present disclosure, the device further includes a fourth obtaining module. The fourth obtaining module is configured to obtain attribute information of the electronic device by calling a third system function.

It should be noted that, descriptions and explanations of embodiments of the method for monitoring a health state of a battery of an electronic device illustrated in FIG. 1 and FIG. 2 are also suitable for embodiments of the device for monitoring a health state of a battery of an electronic device, which is not elaborated herein.

With the device for monitoring a health state of a battery of an electronic device according to embodiments of the present disclosure, when it is determined that the battery of the electronic device is presently in the preset state, the initial electric quantity of the battery is obtained, respective instantaneous current values of the battery are obtained periodically during the preset state at the preset frequency, and when it is determined that the preset state ends, the final electric quantity of the battery is obtained, the present actual capacity of the battery is determined based on the initial electric quantity of the battery, the respective instantaneous current values and the final electric quantity of the battery, and then the present health state of the battery is determined based on the present actual capacity and the design capacity of the battery. Thus, the health condition of the battery can be timely and accurately judged, which can help the user quickly and accurately know the health condition of the battery of the electronic device in use, such that the user can evaluate whether to replace the electronic device or replace the battery of the electronic device based on the health condition of the battery, reliability for battery monitoring can be improved, and user experience can be improved.

In order to achieve the above embodiments, the present disclosure further provides an electronic device.

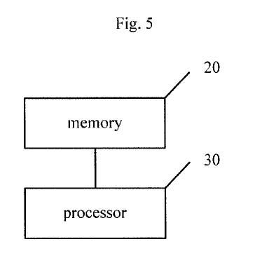

FIG. 5 is a block diagram of an electronic device according to an embodiment of the present disclosure.

As illustrated in FIG. 5, the electronic device includes a memory 20, a processor 30 and a computer program stored in the memory 20 and executable on the processor 30. When the computer program is executed by the processor 30, the method for monitoring a health state of a battery of an electronic device according to embodiments of the present disclosure is implemented. The method includes: obtaining an initial electric quantity of the battery when determining that the battery of the electronic device is presently in a preset state; obtaining respective instantaneous current values of the battery periodically during the preset state at a preset frequency; obtaining a final electric quantity of the battery when determining that the preset state ends; determining a present actual capacity of the battery based on the initial electric quantity of the battery, the respective instantaneous current values and the final electric quantity of the battery; and determining a present health state of the battery based on the present actual capacity and a design capacity of the battery.

It should be noted that, for the implementation process and technical principles of the electronic device according to embodiments of the present disclosure, reference may be made to the foregoing description of the method for monitoring a health state of a battery of an electronic device, and details are not elaborated herein.

With the electronic device according to embodiments of the present disclosure, when it is determined that the battery of the electronic device is presently in the preset state, the initial electric quantity of the battery is obtained, respective instantaneous current values of the battery are obtained periodically during the preset state at the preset frequency, and when it is determined that the preset state ends, the final electric quantity of the battery is obtained, the present actual capacity of the battery is determined based on the initial electric quantity of the battery, the respective instantaneous current values and the final electric quantity of the battery, and then the present health state of the battery is determined based on the present actual capacity and the design capacity of the battery. Thus, the health condition of the battery can be timely and accurately judged, which can help the user quickly and accurately know the health condition of the battery of the electronic device in use, such that the user can evaluate whether to replace the electronic device or replace the battery of the electronic device based on the health condition of the battery, reliability for battery monitoring can be improved, and user experience can be improved.

In order to achieve the above embodiments, the present disclosure further provides a computer readable storage medium. The computer readable storage medium is configured to store a computer program, when the computer program is executed by a processor, the processor is caused to perform the method for monitoring a health state of a battery of an electronic device according to embodiments of the present disclosure. The method includes: obtaining an initial electric quantity of the battery when determining that the battery of the electronic device is presently in a preset state; obtaining respective instantaneous current values of the battery periodically during the preset state at a preset frequency; obtaining a final electric quantity of the battery when determining that the preset state ends; determining a present actual capacity of the battery based on the initial electric quantity of the battery, the respective instantaneous current values and the final electric quantity of the battery; and determining a present health state of the battery based on the present actual capacity and a design capacity of the battery.

Reference throughout this specification to “an embodiment,” “some embodiments,” “an example,” “a specific example,” or “some examples,” means that a particular feature, structure, material, or characteristic described in connection with the embodiment or example is included in at least one embodiment or example of the present disclosure. The appearances of the above phrases in various places throughout this specification are not necessarily referring to the same embodiment or example of the present disclosure. Furthermore, the particular features, structures, materials, or characteristics may be combined in any suitable manner in one or more embodiments or examples. In addition, different embodiments or examples and features of different embodiments or examples described in the specification may be combined by those skilled in the art without mutual contradiction.

In addition, terms such as “first” and “second” are used herein for purposes of description and are not intended to indicate or imply relative importance or significance. Thus, the feature defined with “first” and “second” may comprise one or more this feature. In the description of the present disclosure, unless specified otherwise “a plurality of” means at least two, such as two or three.

Any procedure or method described in the flow charts or described in any other way herein may be understood to comprise one or more modules, portions or parts for storing executable codes that realize particular logic functions or procedures. Moreover, advantageous embodiments of the present disclosure comprises other implementations in which the order of execution is different from that which is depicted or discussed, including executing functions in a substantially simultaneous manner or in an opposite order according to the related functions, which should be understood by those skilled in the art.

The logic and/or step described in other manners herein or shown in the flow chart, for example, a particular sequence table of executable instructions for realizing the logical function, may be specifically achieved in any computer readable medium to be used by the instruction execution system, device or equipment (such as the system based on computers, the system comprising processors or other systems capable of obtaining the instruction from the instruction execution system, device and equipment and executing the instruction), or to be used in combination with the instruction execution system, device and equipment. As to the specification, “the computer readable medium” may be any device adaptive for including, storing, communicating, propagating or transferring programs to be used by or in combination with the instruction execution system, device or equipment. More specific examples of the computer readable medium comprise but are not limited to: an electronic connection (an electronic device) with one or more wires, a portable computer enclosure (a magnetic device), a random access memory (RAM), a read only memory (ROM), an erasable programmable read-only memory (EPROM or a flash memory), an optical fiber device and a portable compact disk read-only memory (CDROM). In addition, the computer readable medium may even be a paper or other appropriate medium capable of printing programs thereon, this is because, for example, the paper or other appropriate medium may be optically scanned and then edited, decrypted or processed with other appropriate methods when necessary to obtain the programs in an electric manner, and then the programs may be stored in the computer memories.

It should be understood that each part of the present disclosure may be realized by the hardware, software, firmware or their combination. In the above embodiments, a plurality of steps or methods may be realized by the software or firmware stored in the memory and executed by the appropriate instruction execution system. For example, if it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a programmable gate array (PGA), a field programmable gate array (FPGA), etc.

It would be understood by those skilled in the art that all or a part of the steps carried by the method in the above-described embodiments may be completed by relevant hardware instructed by a program. The program may be stored in a computer readable storage medium. When the program is executed, one or a combination of the steps of the method in the above-described embodiments may be completed.

In addition, individual functional units in the embodiments of the present disclosure may be integrated in one processing module or may be separately physically present, or two or more units may be integrated in one module. The integrated module as described above may be achieved in the form of hardware, or may be achieved in the form of a software functional module. If the integrated module is achieved in the form of a software functional module and sold or used as a separate product, the integrated module may also be stored in a computer readable storage medium.

The storage medium mentioned above may be read-only memories, magnetic disks or CD, etc. Although explanatory embodiments have been shown and described, it would be appreciated by those skilled in the art that the above embodiments cannot be construed to limit the present disclosure, and changes, alternatives, and modifications can be made in the embodiments without departing from scope of the present disclosure.

What is claimed is:

1. A method for monitoring a health state of a battery of an electronic device, comprising:
obtaining an initial electric quantity of the battery when determining that the battery of the electronic device is presently in a preset state;
obtaining respective instantaneous current values of the battery periodically during the preset state at a preset frequency;
obtaining a final electric quantity of the battery when determining that the preset state ends;
determining a present actual capacity of the battery based on the initial electric quantity of the battery, the respective instantaneous current values and the final electric quantity of the battery; and
determining a present health state of the battery based on the present actual capacity and a design capacity of the battery.

2. The method according to claim 1, wherein determining that the battery of the electronic device is presently in the preset state comprises:
determining that the battery is presently in a discharging state; or
determining that the battery is presently in an alternating current AC charging state.

3. The method according to claim 2, wherein determining that the battery is presently in the AC charging state comprises:
obtaining a system broadcast message sent by the electronic device, wherein the system broadcast message is configured to indicate that an electric quantity of the battery changes; and
determining that the battery is presently in the AC charging state when a value of a preset field in the system broadcast message is consistent with a preset AC charging state value.

4. The method according to claim 1, wherein obtaining the respective instantaneous current values of the battery periodically during the preset state comprises:
calling a first system function periodically, to obtain the respective instantaneous current values of the battery; or
reading a system file of the electronic device periodically, to obtain stored respective instantaneous current values of the battery.

5. The method according to claim 1, wherein before determining the present health state of the battery, the method further comprises:
calling a second system function, to obtain the design capacity of the battery; or
determining the design capacity of the battery according to setting of a user.

6. The method according to claim 1, wherein after obtaining the respective instantaneous current values of the battery periodically, the method further comprises:
determining whether the respective instantaneous current values are within a preset range;
determining a current adjustment coefficient corresponding to the electronic device when the respective instantaneous current values are not within the preset range; and
determining respective actual instantaneous current values of the battery based on the current adjustment coefficient and the respective instantaneous current values.

7. The method according to claim 6, wherein determining the current adjustment coefficient corresponding to the electronic device comprises:
obtaining the current adjustment coefficient corresponding to attribute information of the electronic device by querying a preset database; or
adjusting the respective instantaneous current values by using respective preset adjustment coefficients in sequence to determine respective adjusted instantaneous current values, and determining the adjustment coefficient corresponding to the adjusted instantaneous current values within the preset range as the current adjustment coefficient corresponding to the electronic device; or
adjusting an average value of the respective instantaneous current values by using respective preset adjustment coefficients in sequence to determine adjusted current average values, and determining the adjustment coefficient corresponding to the adjusted current average values within the preset range as the current adjustment coefficient corresponding to the electronic device.

8. An electronic device, comprising:
a memory;
a processor; and
a computer program stored in the memory and executable on the processor,
wherein when the computer program is executed by the processor, the processor is configured to:
obtain an initial electric quantity of the battery when determining that the battery of the electronic device is presently in a preset state;
obtain respective instantaneous current values of the battery periodically during the preset state at a preset frequency;
obtain a final electric quantity of the battery when determining that the preset state ends;
determine a present actual capacity of the battery based on the initial electric quantity of the battery, the respective instantaneous current values and the final electric quantity of the battery; and
determine a present health state of the battery based on the present actual capacity and a design capacity of the battery.

9. The electronic device according to claim 8, wherein when determining that the battery of the electronic device is presently in the preset state, the processor is configured to:
determine that the battery is presently in a discharging state; or
determine that the battery is presently in an alternating current AC charging state.

10. The electronic device according to claim 9, wherein when determining that the battery is presently in the AC charging state, the processor is configured to:
obtain a system broadcast message sent by the electronic device, wherein the system broadcast message is configured to indicate that an electric quantity of the battery changes; and
determine that the battery is presently in the AC charging state when a value of a preset field in the system broadcast message is consistent with a preset AC charging state value.

11. The electronic device according to claim 8, wherein when obtaining the respective instantaneous current values of the battery periodically during the preset state, the processor is configured to:
call a first system function periodically, to obtain the respective instantaneous current values of the battery; or
read a system file of the electronic device periodically, to obtain stored respective instantaneous current values of the battery.

12. The electronic device according to claim 8, wherein the processor is further configured to:
call a second system function, to obtain the design capacity of the battery; or
determine the design capacity of the battery according to setting of a user.

13. The electronic device according to claim 8, wherein the processor is further configured to:
determine whether the respective instantaneous current values are within a preset range;
determine a current adjustment coefficient corresponding to the electronic device when the respective instantaneous current values are not within the preset range; and
determine respective actual instantaneous current values of the battery based on the current adjustment coefficient and the respective instantaneous current values.

14. The electronic device according to claim 13, wherein when determining the current adjustment coefficient corresponding to the electronic device, the processor is configured to:
obtain the current adjustment coefficient corresponding to attribute information of the electronic device by querying a preset database; or
adjust the respective instantaneous current values by using respective preset adjustment coefficients in sequence to determine respective adjusted instantaneous current values, and determine the adjustment coefficient corresponding to the adjusted instantaneous current values within the preset range as the current adjustment coefficient corresponding to the electronic device; or
adjust an average value of the respective instantaneous current values by using respective preset adjustment coefficients in sequence to determine adjusted current average values, and determine the adjustment coefficient corresponding to the adjusted current average values within the preset range as the current adjustment coefficient corresponding to the electronic device.

15. A computer readable storage medium, configured to store a computer program that, when executed by a processor, causes the processor to perform a method for monitoring a health state of a battery of an electronic device, the method comprising:
obtaining an initial electric quantity of the battery when determining that the battery of the electronic device is presently in a preset state;
obtaining respective instantaneous current values of the battery periodically during the preset state at a preset frequency;
obtaining a final electric quantity of the battery when determining that the preset state ends;
determining a present actual capacity of the battery based on the initial electric quantity of the battery, the respective instantaneous current values and the final electric quantity of the battery; and
determining a present health state of the battery based on the present actual capacity and a design capacity of the battery.

16. The computer readable storage medium according to claim 15, wherein determining that the battery of the electronic device is presently in the preset state comprises:
determining that the battery is presently in a discharging state; or
determining that the battery is presently in an alternating current AC charging state.

17. The computer readable storage medium according to claim 16, wherein determining that the battery is presently in the AC charging state comprises:
obtaining a system broadcast message sent by the electronic device, wherein the system broadcast message is configured to indicate that an electric quantity of the battery changes; and
determining that the battery is presently in the AC charging state when a value of a preset field in the system broadcast message is consistent with a preset AC charging state value.

18. The computer readable storage medium according to claim 15, wherein obtaining the respective instantaneous current values of the battery periodically during the preset state comprises:
calling a first system function periodically, to obtain the respective instantaneous current values of the battery; or
reading a system file of the electronic device periodically, to obtain stored respective instantaneous current values of the battery.

19. The computer readable storage medium according to claim 15, wherein before determining the present health state of the battery, the method further comprises:
calling a second system function, to obtain the design capacity of the battery; or
determining the design capacity of the battery according to setting of a user;
wherein after obtaining the respective instantaneous current values of the battery periodically, the method further comprises:
determining whether the respective instantaneous current values are within a preset range;
determining a current adjustment coefficient corresponding to the electronic device when the respective instantaneous current values are not within the preset range; and
determining respective actual instantaneous current values of the battery based on the current adjustment coefficient and the respective instantaneous current values.

20. The computer readable storage medium according to claim 19, wherein determining the current adjustment coefficient corresponding to the electronic device comprises:
obtaining the current adjustment coefficient corresponding to attribute information of the electronic device by querying a preset database; or
adjusting the respective instantaneous current values by using respective preset adjustment coefficients in sequence to determine respective adjusted instantaneous current values, and determining the adjustment coefficient corresponding to the adjusted instantaneous current values within the preset range as the current adjustment coefficient corresponding to the electronic device; or
adjusting an average value of the respective instantaneous current values by using respective preset adjustment coefficients in sequence to determine adjusted current average values, and determining the adjustment coefficient corresponding to the adjusted current average values within the preset range as the current adjustment coefficient corresponding to the electronic device.
